(19) United States
(12) Patent Application Publication
(10) Pub. No.: US 2008/0143441 A1
(43) Pub. Date: Jun. 19, 2008

(54) AMPLIFIER HAVING PLURALITY OF DIFFERENTIAL PAIRS AND COMMUNICATION SYSTEM EQUIPPED WITH SAME

(75) Inventor: Tomohiro Naito, Anpachi-gun (JP)

Correspondence Address: FISH & RICHARDSON P.C., P.O. BOX 1022, MINNEAPOLIS, MN, 55440-1022, US

(73) Assignee: SANYO ELECTRIC CO., LTD., Osaka (JP)

(21) Appl. No.: 11/937,174

(22) Filed: Nov. 8, 2007

(30) Foreign Application Priority Data
Nov. 9, 2006 (JP) 2006-304325

(51) Int. Cl. H03F 3/45

(52) U.S. Cl. 330/258; 330/252

(57) ABSTRACT

A first differential pair and a second differential pair each receive differential input signals. The first differential pair and the second differential pair are connected such that the second differential pair receives part of a tail current of the first differential pair, and such that output signals of the first differential pair and output signals of the second differential pair cancel each other. A constant current source supplies the tail current to the first differential pair. A transistor which functions as a variable current source is connected between a current path and the second differential pair, and supplies a current drawn from the current path to the second differential pair, the current path connecting the first differential pair and the constant current source.

### CROSS-REFERENCE TO RELATED APPLICATIONS

This application is based upon and claims the benefit of priority from the prior Japanese Patent Application No. 2006-304325, filed on Nov. 9, 2006, the entire contents of which are incorporated herein by reference.

### BACKGROUND OF THE INVENTION

1. Field of the Invention

The present invention relates to an amplifier having a plurality of differential pairs, and a communication system equipped with the same.

2. Description of the Related Art

Communication systems are often equipped with variable gain amplifiers. The variable gain amplifiers mounted on communication systems often require a wide range of gain adjustment and low distortion characteristics. In particular, OFDM (Orthogonal Frequency Division Multiplexing) receiving systems and the like require a high linearity.

To meet such requirements, Gilbert cell variable gain amplifiers have been proposed. A Gilbert cell variable gain amplifier includes a high gain differential pair and a low gain differential pair, and changes the ratio of the currents to be passed through the respective differential pairs for gain variation.

### SUMMARY OF THE INVENTION

One embodiment of the present invention is an amplifier including a first differential pair and a second differential pair which each receive differential input signals. The first differential pair and the second differential pair are connected such that the second differential pair receives part of a tail current of the first differential pair, and such that output signals of the first differential pair and output signals of the second differential pair cancel each other.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram showing the circuit configuration of a Gilbert cell variable gain amplifier;

FIG. 2 is a chart showing the characteristic between a gain control signal Vc and a small signal gain Gv of the variable gain amplifier shown in FIG. 1;

FIG. 3 is a diagram showing the circuit configuration of an amplifier according to a typical embodiment of the present invention;

FIG. 4 is a chart showing the characteristic between the gain control signal Vc and the small signal gain Gv of the amplifier according to the embodiment;

FIG. 5 is a diagram showing the circuit configuration of a transconductance amplifier according to practical example 1 of embodiment 1;

FIG. 6 is a diagram showing the circuit configuration of a transconductance amplifier according to practical example 2 of embodiment 1;

FIG. 7 is a diagram showing the circuit configuration of a transconductance amplifier according to practical example 3 of embodiment 1;

FIG. 8 is a diagram showing the circuit configuration of a transconductance amplifier according to practical example 4 of embodiment 1;

FIG. 9 is a diagram showing the circuit configuration of a transconductance amplifier according to practical example 5 of embodiment 1;

FIG. 10 is a diagram showing the circuit configuration of a transconductance amplifier according to practical example 6 of embodiment 1;

FIG. 11 is a diagram showing the circuit configuration of a transconductance amplifier according to embodiment 2;

FIG. 12 is a diagram showing the circuit configuration of a voltage amplifier according to practical example 1 of embodiment 3;

FIG. 13 is a diagram showing the circuit configuration of a voltage amplifier according to practical example 2 of embodiment 3;

FIG. 14 is a diagram showing the circuit configuration of a voltage amplifier according to practical example 3 of embodiment 3;

FIG. 15 is a diagram showing the circuit configuration of a voltage amplifier according to practical example 4 of embodiment 3;

FIG. 16 is a diagram showing the circuit configuration of a voltage amplifier according to practical example 5 of embodiment 3; and

FIG. 17 is a diagram showing a communication system to which the amplifiers of the embodiments are applied.

### DETAILED DESCRIPTION OF THE INVENTION

The invention will now be described by reference to the preferred embodiments. This does not intend to limit the scope of the present invention, but to exemplify the invention.

Before describing embodiments of the present invention in detail, a description will initially be given of a typical mode for implementing the embodiments. One embodiment of the present invention includes a first differential pair and a second differential pair which each receive differential input signals. The first differential pair and the second differential pair are connected such that the second differential pair receives part of a tail current of the first differential pair, and such that output signals of the first differential pair and output signals of the second differential pair cancel each other.

According to this embodiment, the second differential pair receives part of the tail current of the first differential pair, whereby the total sum of the currents to flow through the two differential pairs is kept substantially constant. This makes it possible to implement gain control with a simple configuration.

The amplifier may further include: a constant current source which supplies the tail current of the first differential pair; and a variable current source which is connected between a current path and the second differential pair, and supplies a current drawn from the current path to the second differential pair, the current path connecting the first differential pair and the constant current source. The variable current source may adjust the amount of current to be drawn from the current path in response to an external control signal. As a result, the gain of this amplifier can be controlled by controlling one current source.

The variable current source is set to operate in an area where harmonics of nth order (n is an odd number not smaller than 3) included in the output signals of the first differential pair and the output signals of the second differential pair cancel each other. Since the common sources of the respective differential pairs have a voltage potential difference therebetween, it is possible to create an operating point for canceling the nth-order harmonics without canceling the signals.

Another embodiment of the present invention is also an amplifier. This amplifier includes: a first differential pair which receives differential input signals; and a group of second differential pairs, the group containing a plurality of differential pairs which are connected in parallel and each receive the differential input signals. The first differential pair and the group of second differential pairs are connected such that the group of second differential pairs receive part of a tail current of the first differential pair, and such that output signals of the first differential pair and output signals of the group of second differential pairs cancel each other. The amplifier may further include: a constant current source which supplies the tail current of the first differential pair; and a plurality of variable current sources connected between a current path and the respective plurality of differential pairs included in the group of second differential pairs, the current path connecting the first differential pair and the constant current source. The plurality of variable current sources may individually adjust the amounts of current to be drawn from the current path, in response to respective external control signals.

According to this embodiment, the group of second differential pairs receive part of the tail current of the first differential pair, whereby the total sum of the currents to flow through the group of second differential pairs and the first differential pair is kept substantially constant. This makes it possible to implement gain control with a simple configuration. In addition, the plurality of differential pairs included in the group of second differential pairs can be used selectively for digital ON/OFF control.

The amplifier may further include a common-mode feedback circuit which adjusts direct-current components of differential output signals of the amplifier to a predetermined voltage. This can improve the precision of the output signals.

Still another embodiment of the present invention is a communication system. This communication system includes: a local oscillator which oscillates at a predetermined frequency; a frequency conversion circuit which mixes an oscillation signal from the local oscillator and a signal received by an antenna; and the amplifier according to any one of the foregoing embodiments, which amplifies a signal generated by the frequency conversion circuit.

According to this embodiment, it is possible to achieve a high linearity across a wide range of gain adjustment with an improvement in the precision of the reception signal.

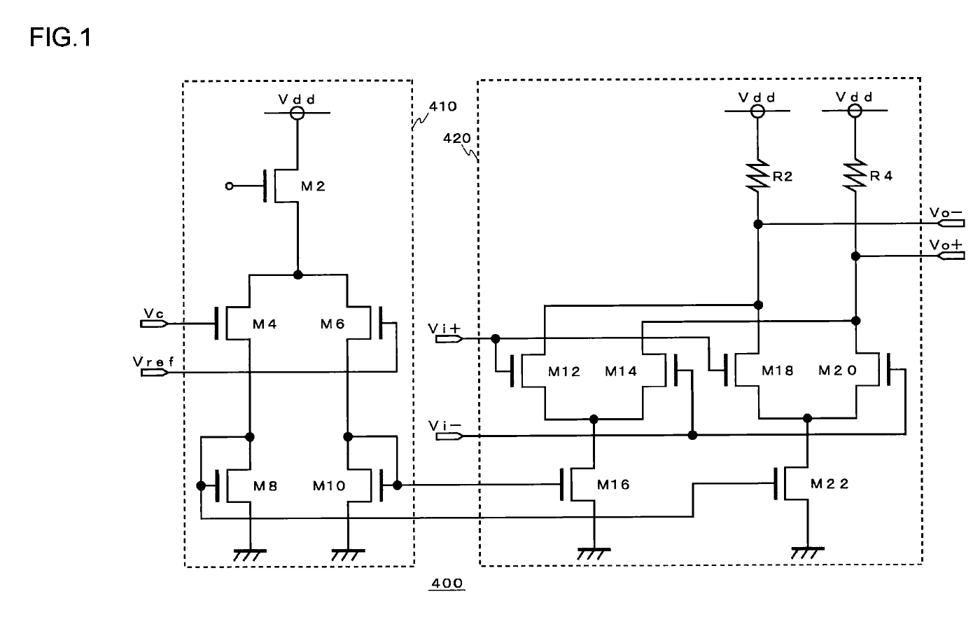

FIG. 1 shows the circuit configuration of a Gilbert cell variable gain amplifier 400 to be compared with the embodiments of the present invention. This variable gain amplifier 400 includes an interface unit 410 and an amplifier unit 420. The amplifier unit 420 includes a first resistor R2, a second resistor R4, a sixth transistor M12, a seventh transistor M14, an eighth transistor M16, a ninth transistor M18, a tenth transistor M20, and an eleventh transistor M22. Hereinafter, the transistors shall be N-channel MOSFETs (Metal-Oxide-Semiconductor Field Effect Transistors) which are formed by CMOS (Complementary Meta-Oxide Semiconductor) processes, unless otherwise specified.

The sixth transistor M12 and the seventh transistor M14 constitute a high gain differential pair. The ninth transistor M18 and the tenth transistor M20 constitute a low gain differential pair. A positive input signal Vi+ is input to the gate terminals of the sixth transistor M12 and the ninth transistor M18. A negative input signal Vi− is input to the gate terminals of the seventh transistor M14 and the tenth transistor M20. The drain terminal of the eighth transistor M16 is connected to the source terminals of the sixth transistor M12 and the seventh transistor M14 in common. The source terminal of the eighth transistor M16 is grounded. The eighth transistor M16 functions as a current source for supplying a bias current to the high gain differential pair. Similarly, the drain terminal of the eleventh transistor M22 is connected to the source terminals of the ninth transistor M18 and the tenth transistor M20 in common. The source terminal of the eleventh transistor M22 is grounded. The eleventh transistor M22 functions as a current source for supplying a bias current to the low gain differential pair.

The first resistor R2 and the second resistor R4 function as loads. One end of the first resistor R2 is connected to the drain terminals of the sixth transistor M12 and the ninth transistor M18 in common. The voltage at the connection point is a negative output voltage Vo−. The other end of the first resistor R2 is connected to a power supply Vdd. Similarly, one end of the second resistor R4 is connected to the drain terminals of the seventh transistor M14 and the tenth transistor M20 in common. The voltage at the connection point is a positive output voltage Vo+. The other end of the second resistor R4 is connected to the power supply Vdd. The first resistor R2 is shared between the transistors that have a negative output polarity in the high gain differential pair and the low gain differential pair described above. The second resistor R4 is shared between the transistors that have a positive output polarity in the high gain differential pair and the low gain differential pair described above.

The interface unit 410 functions as a gain control circuit for controlling the gain of the amplifier unit 420. The interface unit 410 has the role of maintaining the total sum of the currents to flow the foregoing high and low gain differential pairs constant while changing the currents in a complementary fashion. The interface unit 410 includes a first transistor M2, a second transistor M4, a third transistor M6, a fourth transistor M8, and a fifth transistor M10. A fixed reference voltage Vref is input to the gate terminal of the third transistor M6. A gain control signal Vc is input to the gate terminal of the second transistor M4. The drain terminal of the first transistor M2 is connected to the power supply Vdd. The source terminal of the first transistor M2 is connected to the drain terminals of the second transistor M4 and the third transistor M6 in common. A predetermined bias voltage is applied to the gate terminal of the first transistor M2, so that the first transistor M2 functions as a constant current source for supplying a bias current to the second transistor M4 and the third transistor M6.

The drain terminal of the fourth transistor M8 is connected with the source terminal of the second transistor M4. The source terminal of the fourth transistor M8 is grounded. The gate terminal and the drain terminal of the fourth transistor M8 are diode-connected. The gate terminal of the fourth transistor M8 and the gate terminal of the eleventh transistor M22 are connected to constitute a current mirror circuit. Similarly, the drain terminal of the fifth transistor M10 is connected to the source terminal of the third transistor M6. The source terminal of the fifth transistor M10 is grounded. The gate terminal and the drain terminal of the fifth transistor M10 are diode-connected. The gate terminal of the fifth transistor M10 and the gate terminal of the eighth transistor M16 are connected to constitute a current mirror circuit.

In the variable gain amplifier 400 configured as described above, the ratio of the currents to flow through the fourth transistor M8 and the fifth transistor M10 varies depending on a change in the gain control signal Vc mentioned above. Since the fourth transistor M8 and the fifth transistor M10 constitute current mirror circuits with the eighth transistor M16 and the tenth transistor M20, respectively, the ratio of the bias currents to be supplied to the high gain differential pair and the low gain differential pair also varies with the foregoing current ratio.

Even if the ratio between the amounts of current to flow through the respective high and low gain differential pairs, i.e., (1−α) : α [0≦α≦1] varies, the amounts of direct current to flow through the respective first and second resistors R2 and R4 are kept constant. The voltage drops occurring from the first resistor R2 and the second resistor R4 are thus kept constant, so that the direct-current components of the output voltages Vo remain unchanged.

Meanwhile, the gains Gv of the small signals Vi input to the gate terminals of the sixth transistor M12 and the ninth transistor M18 and the gate terminals of the seventh transistor M14 and the tenth transistor M20 vary with the bias currents that flow through the respective differential pairs. For example, when the gain control signal Vc=the reference voltage Vref, the bias currents flowing through the respective differential pairs have the same value and the output signals of the two differential pairs have the same amplitude. Consequently, the output signals cancel each other, and this variable gain amplifier 400 provides zero gain.

The small signal gain Gv is expressed by the following equation (Eq. 1):

Gv=−gm·R1, . . . (Eq. 1)

where gm is the mutual conductance, and R1 is a load resistance. The sign “−” indicates the reversal of polarity.

The mutual conductance gm is expressed by the following equation (Eq. 2):

gm=√2βI_{d}, (Eq. 2)

where P is a device parameter proportional to the ratio between the channel width and the channel length of the transistor, and I_{d} is the direct-current bias current. That is, the gain Gv of the small signal Vi varies depending on a change in bias current.

The small signal gain Gv of this variable gain amplifier 400 is expressed by the following equation (Eq. 3):

Gv=−{√2β(1−α)I_{d}+√2βαI_{d}}·R1 (Eq. 3)

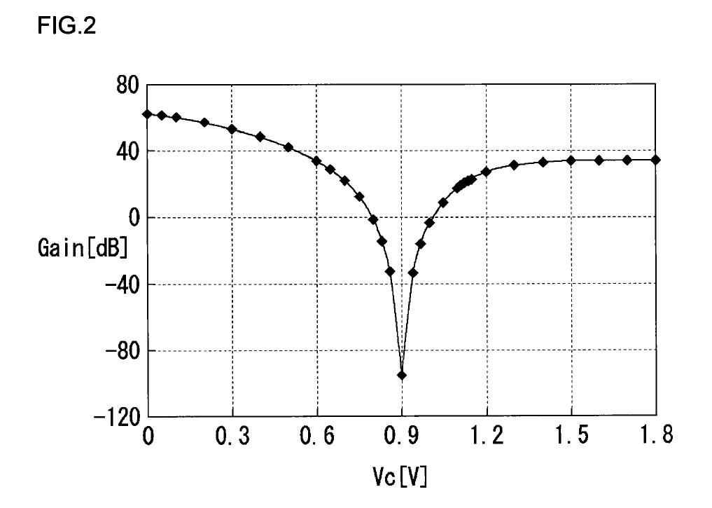

FIG. 2 is a chart showing the characteristic between the gain control signal Vc and the small signal gain Gv of the variable gain amplifier 400 shown in FIG. 1. As shown in FIG. 2, this variable gain amplifier 400 traces a Vc-Gv curve with a V shape.

Next, a description will be given of the embodiments of the present invention.

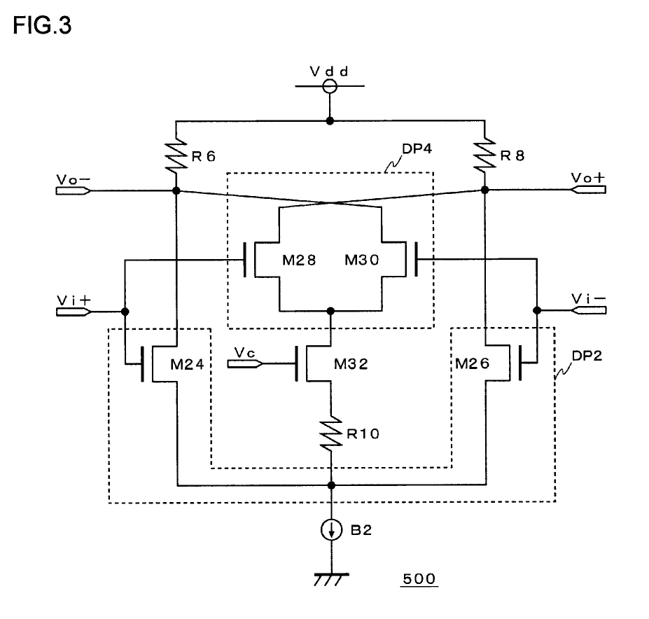

FIG. 3 shows the circuit configuration of an amplifier 500 according to a typical embodiment of the present invention. The amplifier 500 includes a third resistor R6, a fourth resistor R8, a first differential pair DP2, a second differential pair DP4, a sixteenth transistor M32, a fifth resistor R10, and a constant current source B2. The first differential pair DP2 includes a twelfth transistor M24 and a thirteenth transistor M26. The second differential pair DP4 includes a fourteenth transistor M28 and a fifteenth transistor M30.

A positive input signal Vi+ is input to the gate terminals of the twelfth transistor M24 and the fourteenth transistor M28. A negative input signal Vi− is input to the gate terminals of the thirteenth transistor M26 and the fifteenth transistor M30.

The constant current source B2 supplies a first tail current to the first differential pair DP2. In this instance, the first tail current refers to the sum of the bias currents to be passed through the twelfth transistor M24 and the thirteenth transistor M26 which constitute the first differential pair DP2. One end of the constant current source B2 is connected in common to the source terminals of the twelfth transistor M24 and the thirteenth transistor M26 which constitute the first differential pair DP2. The other end of the constant current source B2 is grounded.

The sixteenth transistor M32 functions as a variable tail current source for supplying a second tail current to the second differential pair DP4. In this instance, the second tail current refers to the sum of the bias currents to be passed through the fourteenth transistor M28 and the fifteenth transistor M30 which constitute the second differential pair DP4. The second tail current is a current drawn from the first tail current. The drain terminal of the sixteenth transistor M32 is connected in common to the source terminals of the fourteenth transistor M28 and the fifteenth transistor M30 which constitute the second differential pair DP4. The source terminal of the sixteenth transistor M32 is connected to the source terminals of the twelfth transistor M24 and the thirteenth transistor M26, which constitute the first differential pair DP2, and also to the constant current source B2 in common through the fifth resistor R10. A gain control signal Vc is input to the gate terminal of the sixteenth transistor M32.

The third resistor RG and the fourth resistor R8 function as loads. One end of the third resistor R6 is connected to the drain terminals of the twelfth transistor M24 and the fifteenth transistor M30 in common. The voltage at the connection point is a negative output voltage Vo−. The other end of the third resistor R6 is connected to a power supply Vdd. Similarly, one end of the fourth resistor R8 is connected to the drain terminals of the thirteenth transistor M26 and the fourteenth transistor M28 in common. The voltage at the connection point is a positive output voltage Vo+. The other end of the fourth resistor R8 is connected to the power supply Vdd. The output signals of twelfth transistor M24 and the fifteenth transistor M30, which share the third resistor R6, are opposite in polarity. Similarly, the output signals of the thirteenth transistor M26 and the fourteenth transistor M28, which share the fourth resistor R8, are opposite in polarity.

In the amplifier 500 according to the present embodiment, the input signals Vi are amplified by the first differential pair DP2 and the second differential pair DP4, respectively, and cancel each other at the output points. The degree of canceling depends on the gate voltage of the sixteenth transistor M32. The gate voltage of the sixteenth transistor M32 is controlled by the gain control signal Vc, and the current that the second differential pair DP4 receives from the constant current source B2 varies with the change in the gate voltage. The gain peaks when the gate voltage is 0 V, and decreases with increasing gate voltage. The direct current bias currents that flow through the loads are constant irrespective of the ratio between the currents that flow through the first differential pair DP2 and the second differential pair DP4.

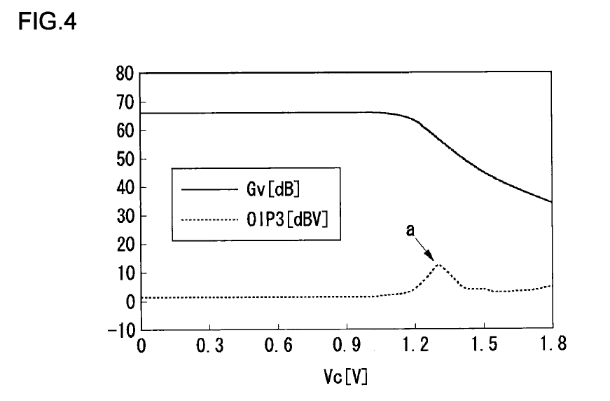

FIG. 4 is a chart showing the characteristic between the gain control signal Vc and the small signal gain Gv of the amplifier 500 according to the present embodiment. In FIG. 4, the solid line shows the Vc-Gv characteristic which is monotonically decreasing. The dotted line shows an OIP3 (third order intercept point) characteristic. OIP3 is a linear index for output conversion, and is given by OIP3=IIP3+Gv.

Hereinafter, the amplifier 500 according to the present embodiment will be compared with the Gilbert cell variable gain amplifier 400 shown in FIG. 1.

Turning first to the amplifier 500 according to the present embodiment, the direct currents that flow through the loads are constant irrespective of which operating area the sixteenth transistor M32 functioning as a variable current source is in. The gate voltage of the sixteenth transistor M32 may have any value from 0 V up to the power supply voltage Vdd. Functioning as the variable current source, the sixteenth transistor M32 receives part of the current from the constant current source B2, and supplies the received current to the second differential pair DP4 as the second tail current. The constant current source B2 supplies the rest of the current, i.e., the first tail current minus the second tail current, to the first differential pair DP2.

Consequently, the total sum of the currents output to the first differential pair DP2 and the second differential pair DP4 is always constant. As a result, it is possible to suppress variations in the direct-current components of the output voltages, and suppress a drop in linearity ascribable to the variations.

By contrast, in the Gilbert cell variable gain amplifier 400, the total sum of the currents that flow through the two differential pairs may vary slightly due to the channel length modulation effects of the transistors. In addition, when the gain control voltage is changed significantly, the transistors M2, M4, M6, M8, and M10 included in the interface unit 410 may exceed their saturation areas. In that case, the total sum of the currents can vary significantly. In consequence, the direct current components of the output voltages will no longer be constant, which shrinks the output range and increases distortion in the output signals.

As shown in FIG. 4, the amplifier 500 according to the present embodiment has the monotonically-decreasing Vc-Gv characteristic and is less likely to go out of AGC (Automatic Gain Control) lock. In contrast, the Gilbert cell variable gain amplifier 400 has the V-shaped Vc-Gv characteristic as shown in FIG. 2, and is thus likely to go out of AGC lock. The remedy for this would require an additional adjusting circuit to prevent the gain control signal Vc from going out of a monotonically increasing or monotonically decreasing range.

For these reasons, the Gilbert cell variable gain amplifier 400 requires a complicated interface circuit. Conversely, the amplifier 500 according to the present embodiment can control the current ratio between the two differential pairs simply by controlling the gate voltage of the sixteenth transistor M32. It is therefore possible to entirely omit the complicated interface circuit.

Moreover, the amplifier 500 according to the present embodiment can also improve the linearity at low gains by canceling the third-order harmonics mutually between the two differential pairs. In the amplifier 500 according to the present embodiment, the sixteenth transistor M32 is interposed between the common sources of the two differential pairs, thereby causing a voltage potential difference between the common sources. That is, the two differential pairs have a difference in operation. As shown in FIG. 4, this consequently creates an operating point a where the harmonics alone are canceled, not the signals. The linearity improves significantly at this distortion-canceling point a. The amplifier 500 according to the present embodiment functions to cancel distortion effectively even at operating points somewhat off the distortion-canceling point a, though with some drop in canceling effectiveness. This makes it possible to improve the linearity across a wide range of gain adjustment. In addition, the value of the fifth resistor R10 can be changed to adjust the position of the distortion-canceling point a. This distortion canceling is also effective to the harmonics of fifth and higher order.

The Gilbert cell variable gain amplifier 400, in contrast, causes little difference in potential between the two common sources, and has difficulty in creating the distortion-canceling point in a desired position. It is therefore difficult to make effective use of the distortion canceling effect. The Gilbert cell variable gain amplifier 400 provides only an insufficient linearity when operating at low gains. In general, communication apparatuses operating at low gains require an improved linearity corresponding to drops in gain from when operating at high gains. The Gilbert cell variable gain amplifier 400 cannot provide a sufficient improvement in linearity.

Hereinafter, various embodiments of the present invention will be described. Initially, a description will be given of embodiment 1.

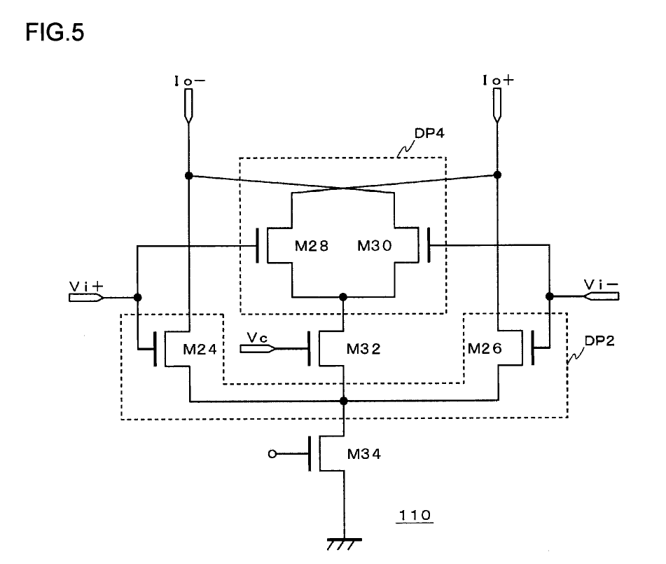

FIG. 5 is a diagram showing the circuit configuration of a transconductance amplifier 110 according to practical example 1 of embodiment 1. The transconductance amplifier 110 according to this practical example 1 is configured by omitting the third resistor R6 and the fourth resistor R8, which function as loads, and the fifth resistor R10, which is intended to adjust the distortion-canceling point, from the amplifier 500 described in FIG. 3. Furthermore, the constant current source B2 is provided as a seventeenth transistor M34. The transconductance amplifier 110 according to this practical example 1 makes the same operations as those of the amplifier 500 described in FIG. 3, except that the outputs are taken out in the form of currents. A description thereof will thus be omitted. The functions and effects are also the same.

Now, variations of the transconductance amplifier 110 according to practical example 1 of embodiment 1 will be described.

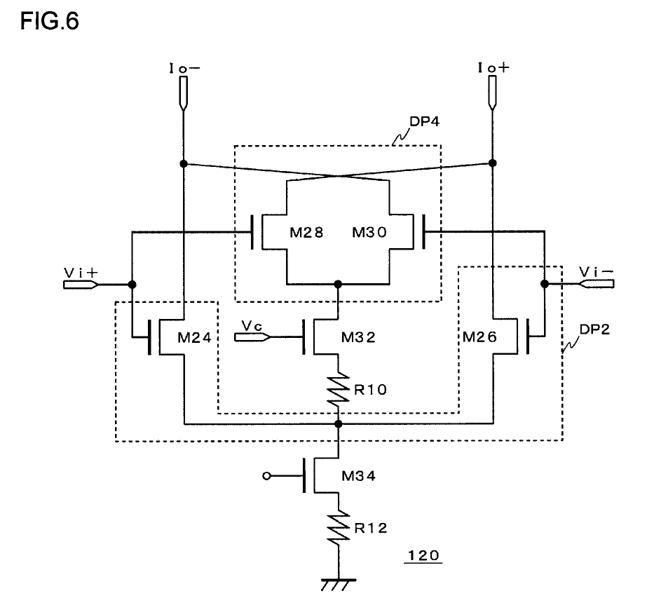

FIG. 6 is a diagram showing the circuit configuration of a transconductance amplifier 120 according to practical example 2 of embodiment 1. The transconductance amplifier 120 according to practical example 2 is configured according to practical example 1, except that the fifth resistor R10 is connected to the source terminal of the sixteenth transistor M32 of the transconductance amplifier 110, and the sixth resistor R12 is connected to the source terminal of the seventeenth transistor M34. The insertion of these resistors makes it possible to adjust the distortion-canceling point and the voltage-current conversion efficiency of this transconductance amplifier 120.

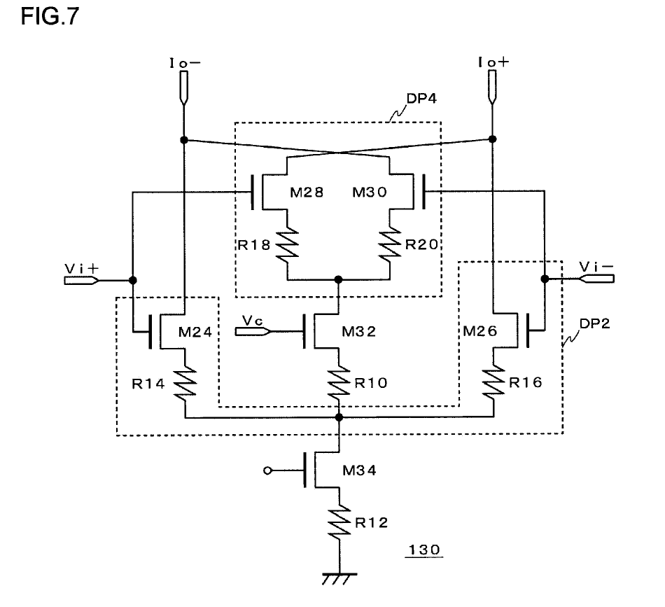

FIG. 7 is a diagram showing the circuit configuration of a transconductance amplifier 130 according to practical example 3 of embodiment 1. The transconductance amplifier 130 according to practical example 3 is configured according to practical example 2, except that: the seventh resistor R14 is connected to the source terminal of the twelfth transistor M24 of the transconductance amplifier 120; the eighth resistor R16 is connected to the source terminal of the third transistor M26; the ninth resistor R18 is connected to the source terminal of the fourteenth transistor M28; and the tenth resistor R20 is connected to the source terminal of the fifteenth transistor M30. The insertion of these resistors makes it possible to adjust the distortion-canceling point and the voltage-current conversion efficiency of this transconductance amplifier 130.

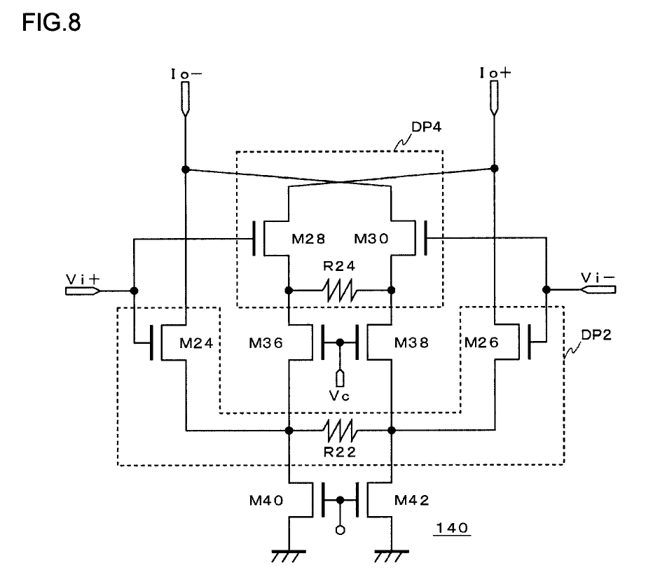

FIG. 8 is a diagram showing the circuit configuration of a transconductance amplifier 140 according to practical example 4 of embodiment 1. The transconductance amplifier 140 according to practical example 4 is configured according to practical example 1, except that: the seventeenth transistor M34 of the transconductance amplifier 110, functioning as a constant tail current source, is replaced with a pair of a twenty-first transistor M42 and a twenty-second transistor M44; and the sixteenth transistor M32, functioning as a variable tail current source, is replaced with a pair of an eighteenth transistor M36 and a nineteenth transistor M38. An eleventh resistor R22 is also interposed between the connection point between the source terminal of the twelfth transistor M24 and the drain terminal of the twentieth transistor M40 and the connection point between the source terminal of the thirteenth transistor M26 and the drain terminal of the twenty-second transistor M42. Similarly, a twelfth resistor R24 is interposed between the connection point between the source terminal of the fourteenth transistor M28 and the drain terminal of the eighteenth transistor M36 and the connection point between the source terminal of the fifteenth transistor M30 and the drain terminal of the nineteenth transistor M38. This configuration of the current sources and the insertion of the resistors makes it possible to adjust the distortion-canceling point and the voltage-current conversion efficiency of this transconductance amplifier 140.

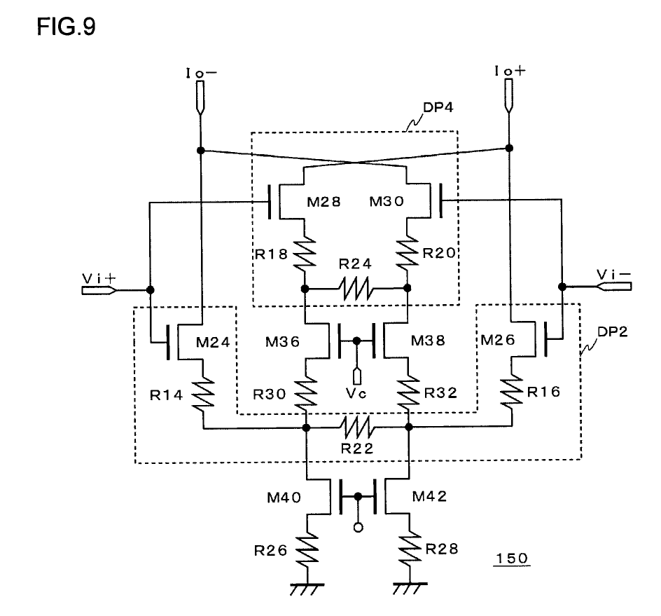

FIG. 9 is a diagram showing the circuit configuration of a transconductance amplifier 150 according to practical example 5 of embodiment 1. The transconductance amplifier 150 according to practical example 5 is configured according to practical example 4, except that resistors are connected to the source terminals of all the transistors included in the transconductance amplifier 140. Specifically, the seventh resistor R14 is connected to the source terminal of the twelfth transistor M24. The eighth resistor R16 is connected to the source terminal of the thirteenth transistor M26. The ninth resistor R18 is connected to the source terminal of the fourteenth transistor M28. The tenth resistor R20 is connected to the source terminal of the fifteenth transistor M30. A thirteenth resistor R26 is connected to the source terminal of the twentieth transistor M40. A fourteenth resistor R28 is connected to the source terminal of the twenty-first transistor M42. A fifteenth resistor R30 is connected to the source terminal of the eighteenth transistor M36. A sixteenth resistor R32 is connected to the source terminal of the nineteenth transistor M38. This configuration of the current sources and the insertion of the resistors makes it possible to adjust the distortion-canceling point and the voltage-current conversion efficiency of this transconductance amplifier 150.

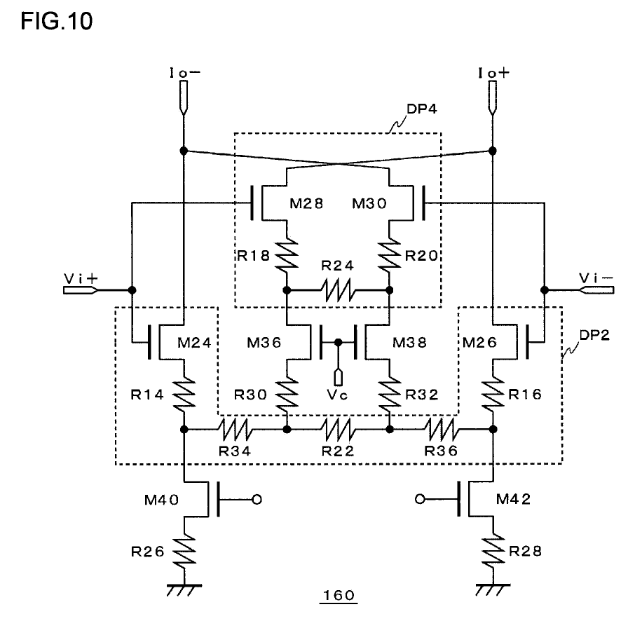

FIG. 10 is a diagram showing the circuit configuration of a transconductance amplifier 160 according to practical example 6 of embodiment 1. The transconductance amplifier 160 according to practical example 6 is configured according to practical example 5, except that a seventeenth resistor R34 and an eighteenth resistor R36 are added to the transconductance amplifier 150. The seventeenth resistor R34 is interposed between the connection point of the seventh resistor R14 and the twentieth transistor M40 and the connection point of the eleventh resistor R22 and the fifteenth resistor R30. The eighteenth resistor R36 is interposed between the connection point of the eighth resistor R16 and the twenty-first transistor M42 and the connection point of the eleventh resistor R22 and the sixteenth resistor R32. This configuration of the current sources and the insertion of the resistors makes it possible to adjust the distortion-canceling point and the voltage-current conversion efficiency of this transconductance amplifier 160.

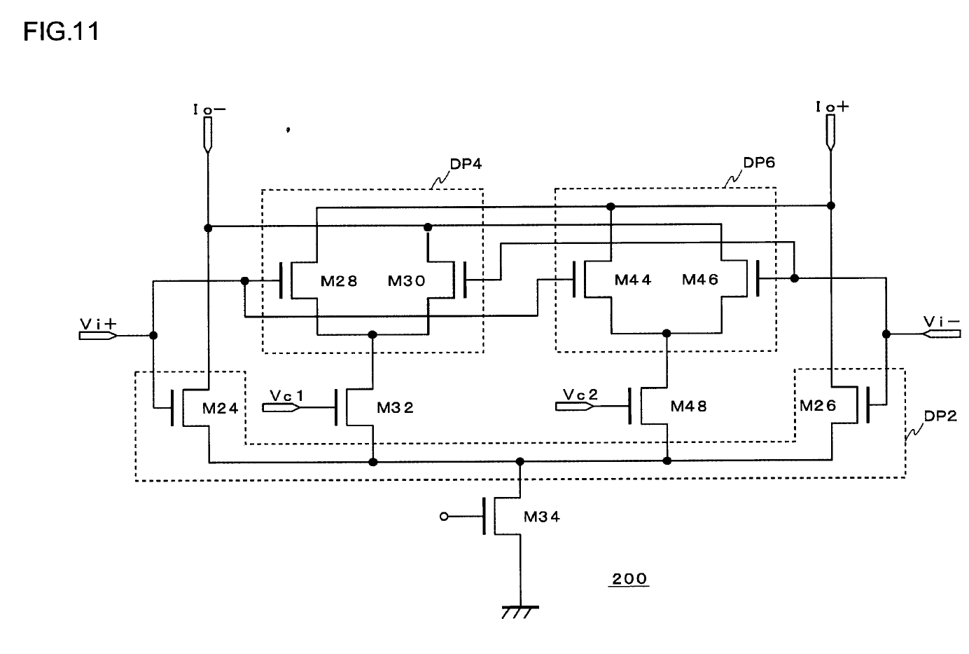

FIG. 11 is a diagram showing the circuit configuration of a transconductance amplifier 200 according to embodiment 2. The transconductance amplifier 200 according to embodiment 2 includes three differential pairs. Specifically, it is configured according to practical example 1 of embodiment 1, except that a third differential pair DP 6 and a twenty-fourth transistor M48 are added to the circuit configuration of the transconductance amplifier 110. The third differential pair DP6 includes a twenty-second transistor M44 and a twenty-third transistor M46. The positive input signal Vi+ is input to the gate terminal of the twenty-second transistor M44. The negative input signal Vi− is input to the gate terminal of the twenty-third transistor M46. The drain terminal of the twenty-second transistor M44 is connected to the positive output signal Io+. The drain terminal of the twenty-third transistor M46 is connected to the negative output signal Io−.

The twenty-fourth transistor M48 functions as a variable tail current source for supplying a third tail current to the third differential pair DP6. In this instance, the third tail current refers to the sum of the bias currents to be passed through the twenty-second transistor M44 and the twenty-third transistor M46, which constitute the third differential pair DP6. The third tail current is a current drawn from the first tail current. The drain terminal of the twenty-fourth transistor M48 is connected in common to the source terminals of the twenty-second transistor M44 and the twenty-third transistor M46, which constitute the third differential pair DP6. The source terminal of the twenty-fourth transistor M48 is connected in common to the source terminals of the twelfth transistor M24 and the thirteenth transistor M26, which constitute the first differential pair DP2, and to the drain terminal of the seventeenth transistor M34. A gain control signal Vc2 is input to the gate terminal of the twenty-fourth transistor M48.

In the transconductance amplifier 200 according to the present embodiment, the second differential pair DP4 and the third differential pair DP6 each receive part of the first tail current of the first differential pair DP2. The output signals of the second differential pair DP4 and the third differential pair DP6 and the output signals of the first differential pair DP2 cancel each other. The gain control signals Vc1 and Vc2 input to the gate terminals of the sixteenth transistor M32 and the twenty-fourth transistor M48 can be changed to adjust the ratios of the currents that flow through the three differential pairs. This consequently changes the voltage-current conversion efficiency. If the gain control signal Vc1 is zero, the second differential pair DP4 turns off. If the gain control signal Vc2 is zero, the third differential pair DP6 turns off. The transconductance amplifier 200 according to the present embodiment can select either one of two Vc-Gv curves by making either of the gain control signals Vc1 and Vc2 zero. If both the second differential pair DP4 and the third differential pair DP6 are on, the characteristics of the second differential pair DP4 and the third differential pair DP6 are merged into a Vc-Gv curve in operation. According to embodiment 2, it is possible to omit the entire complicated interface circuit and achieve a high linearity across a wide range of gain adjustment as with the amplifier 500 described in FIG. 3.

Next, a description will be given of embodiment 3 of the present invention. Embodiment 3 will deal with a voltage amplifier in which a transconductance amplifier having any one of the configurations described in embodiments 1 and 2 is connected with loads.

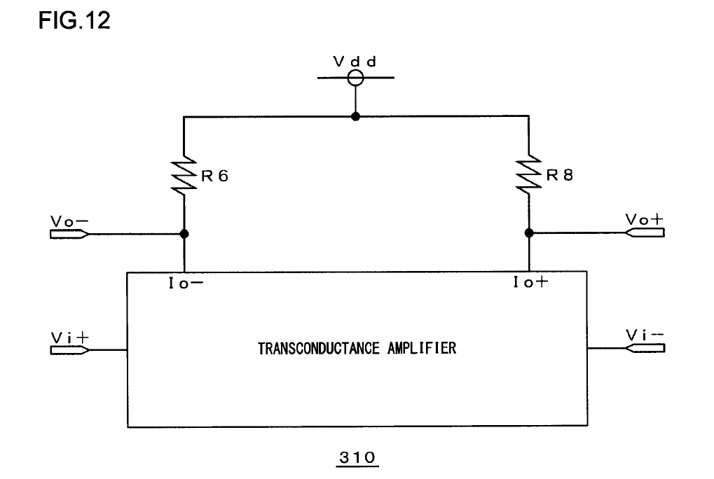

FIG. 12 is a diagram showing the circuit configuration of a voltage amplifier 310 according to practical example 1 of embodiment 3. The voltage amplifier 310 according to practical example 1 is configured so that the third resistor R6 and the fourth resistor RB are connected as loads to the positive and negative current output terminals of the transconductance amplifier, respectively. This provides the same configuration as that of the amplifier 500 described in FIG. 3. Thus, the functions and effects are also the same.

Hereinafter, variations of the voltage amplifier 310 according to practical example 1 of embodiment 3 will be described.

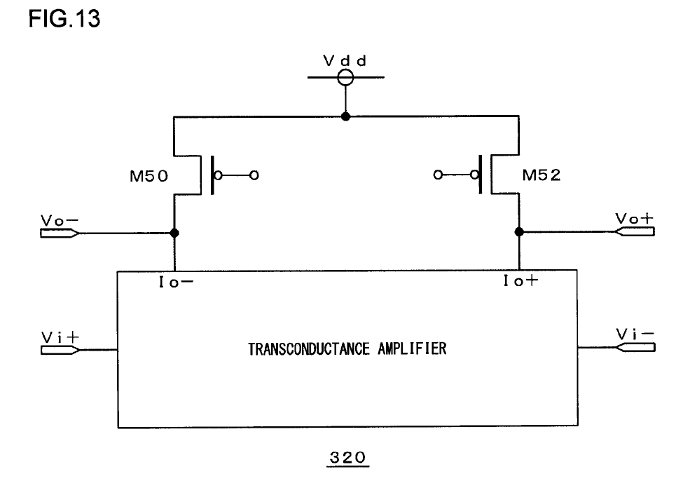

FIG. 13 is a diagram showing the circuit configuration of a voltage amplifier 320 according to practical example 2 of embodiment 3. The voltage amplifier 310 according to practical example 2 is configured so that a twenty-fifth transistor M50 and a twenty-sixth transistor M52 of P-channel type are used as the loads. The drain terminal of the twenty-fifth transistor M50 is connected to the negative output terminal of the transconductance amplifier. The source terminal of the twenty-fifth transistor M50 is connected to the power supply Vdd. A predetermined bias voltage is applied to the gate terminal of the twenty-fifth transistor M50. Similarly, the drain terminal of the twenty-sixth transistor M52 is connected to the positive output terminal of the transconductance amplifier. The source terminal of the twenty-sixth transistor M52 is connected to the power supply Vdd. A predetermined bias voltage is applied to the gate terminal of the twenty-sixth transistor M52. The use of the MOSFETs as the load resistors can reduce the occupied areas as compared to the case of using resistors. The bias conditions and dimensions can also be changed to freely adjust the output resistances.

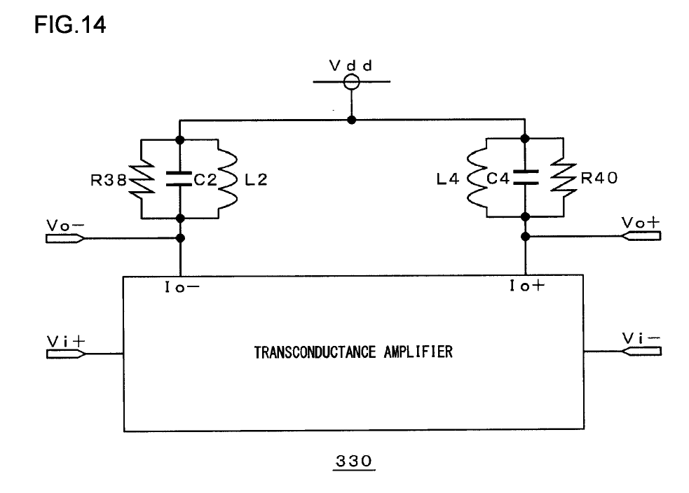

FIG. 14 is a diagram showing the circuit configuration of a voltage amplifier 330 according to practical example 3 of embodiment 3. The voltage amplifier 330 according to embodiment 3 is configured to use oscillators as the loads. An oscillator consisting of a parallel circuit of a first inductor L2, a first capacitor C2, and a nineteenth resistor R38 is interposed between the negative output terminal of the transconductance amplifier and the power supply Vdd. Similarly, an oscillator consisting of a parallel circuit of a second inductor L4, a second capacitor C4, and a twentieth resistor R40 is interposed between the positive output terminal of the transconductance amplifier and the power supply Vdd. Then, it is possible to generate frequencies with which the impedances appear to be infinite.

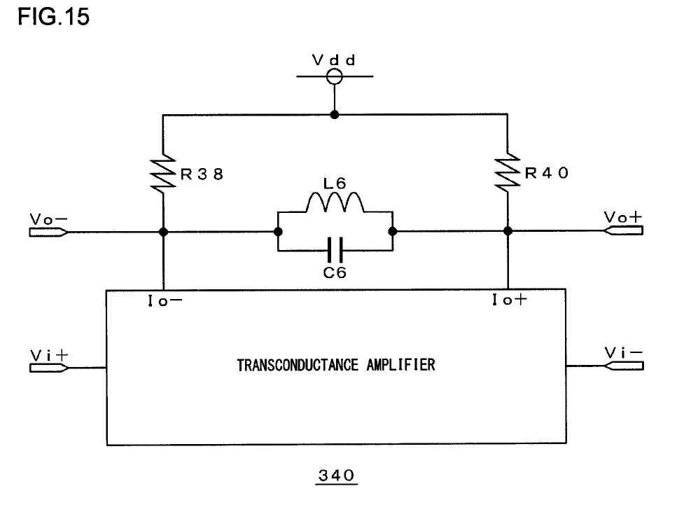

FIG. 15 is a diagram showing the circuit configuration of a voltage amplifier 340 according to practical example 4 of embodiment 3. The voltage amplifier 340 according to practical example 4 is configured so that an LC filter is added to the nineteenth resistor R38 and the twentieth resistor R40 which are connected as the loads. The LC filter interposed between the positive and negative output terminals of the transconductance amplifier is composed of a parallel circuit of a third inductor L6 and a third capacitor C6. The voltage amplifier 340 according to practical example 4 can also achieve the same characteristic as that of the voltage amplifier 330 according to practical example 3.

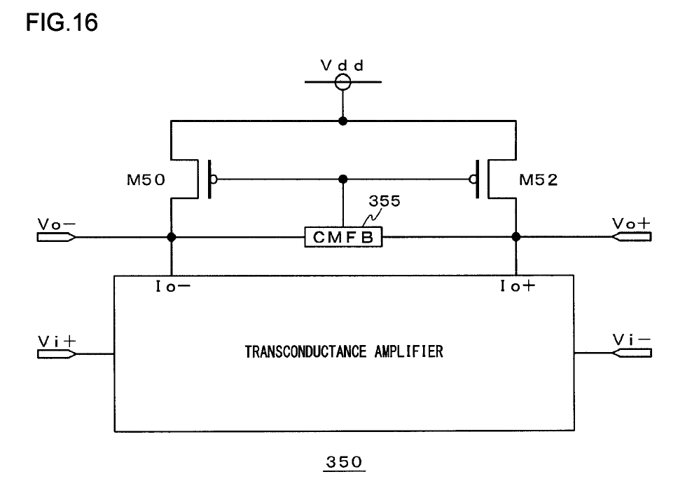

FIG. 16 is a diagram showing the circuit configuration of a voltage amplifier 350 according to practical example 5 of embodiment 3. The voltage amplifier 350 according to practical example 5 is configured according to practical example 2, except that a common-mode feedback (CMFB) circuit 355 is added to the configuration of the voltage amplifier 320. The CMFB circuit 355 performs feedback on the gate terminals of the twenty-fifth transistor M50 and the twenty-sixth transistor M52 so that an average of the two output voltages of this voltage amplifier 350, i.e., the direct-current component thereof is fixed to a predetermined common-mode voltage. By this feedback control, the amounts of current that flow through the twenty-fifth transistor M50 and the twenty-sixth transistor M52 change to adjust the output voltages of this voltage amplifier 350. This makes it possible to maintain the direct-current components of the output voltages constant. According to embodiment 3, it is possible to omit the entire complicated interface circuit and achieve a high linearity across a wide range of gain adjustment as with the amplifier 500 described in FIG. 3.

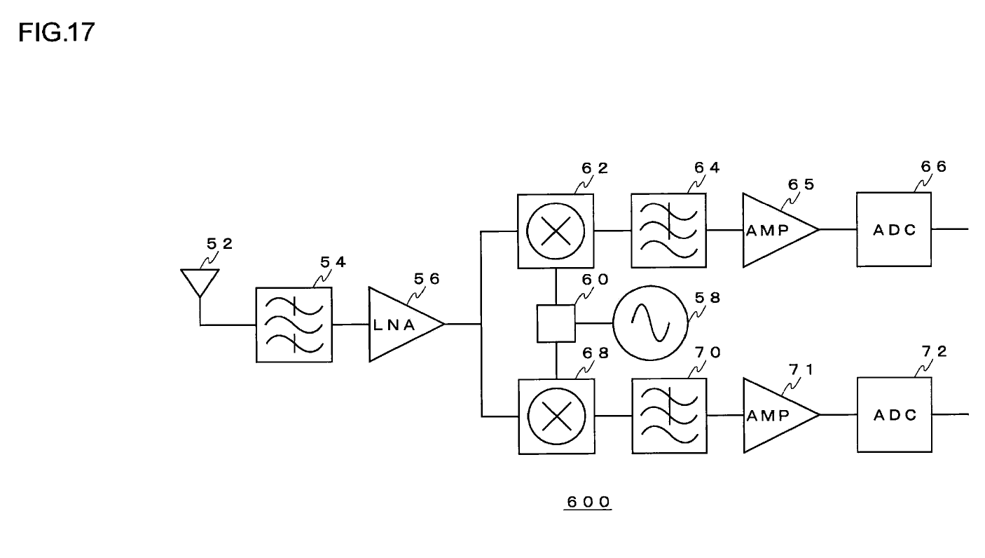

FIG. 17 is a diagram showing a communication system 600 to which the amplifiers of the embodiments are applied. While the communication system 600 shown in FIG. 17 is of direct conversion receiving (DCR) system, it is not limited thereto but may be applied to other receiving systems such as heterodyne receiving system.

In FIG. 17, an RF signal received by an antenna 52 is passed through a band-bass filter 54 and input to a low noise amplifier (LNA) 56. The LNA 56 amplifies the RF signal with low noise, and outputs it to a first frequency conversion circuit 62 and a second frequency conversion circuit 68 which are intended for an I signal and a Q signal of orthogonal baseband signals, respectively.

A local oscillator 58 outputs a local signal having a local (Lo) frequency. A phase shifter 60 outputs the Lo signal to the first frequency conversion circuit 62 on the I system without any phase shift, and outputs the Lo signal to the second frequency conversion circuit 68 on the Q system with a phase shift of 90°.

The first frequency conversion circuit 62 and the second frequency conversion circuit 68 mix the RF signal and the respective Lo signals, and output the signals having respective different frequencies to a second LPF 64 and a third LPF 70, respectively. The output signals of the second LPF 64 and the third LPF 70 are amplified by variable gain amplifiers 65 and 71 on the respective systems. The amplifiers according to the foregoing embodiments may be applied to these variable gain amplifiers 65 and 71. The output signals of the variable gain amplifiers 65 and 71 on the respective systems are converted into digital signals by a first analog-to-digital converter 66 and a second analog-to-digital converter 72, respectively.

As has been described, since the communication system 600 is equipped with any of the amplifiers according to the foregoing embodiments, it is possible to achieve a high linearity across a wide range of gain adjustment with an improvement to the precision of the reception signal.

Up to this point, the present invention has been described in conjunction with the several embodiments thereof. These embodiments have been given solely by way of illustration. It will be understood by those skilled in the art that various modifications may be made to combinations of the foregoing components and processes, and all such modifications are also intended to fall within the scope of the present invention.

The foregoing embodiments have dealt with the cases where the amplifier(s) is/are mainly composed of N-channel MOSFETs. Nevertheless, this is not restrictive, and some of the transistors may be P-channel MOSFETs. In such cases, the high and low levels of the signals to be applied to the gate terminals may be inverted as appropriate. In addition, MOSFETs may be cascaded to incorporate circuit configuration of increased gain when necessary. Moreover, some or all of the transistors constituting the amplifiers may be made of bipolar transistors.

What is claimed is:

1. An amplifier comprising a first differential pair and a second differential pair which each receive differential input signals, wherein
the first differential pair and the second differential pair are connected such that the second differential pair receives part of a tail current of the first differential pair, and such that output signals of the first differential pair and output signals of the second differential pair cancel each other.

2. The amplifier according to claim 1, further comprising:
a constant current source which supplies the tail current of the first differential pair; and
a variable current source which is connected between a current path and the second differential pair, and supplies a current drawn from the current path to the second differential pair, the current path connecting the first differential pair and the constant current source.

3. The amplifier according to claim 2, wherein the variable current source is set to operate in an area where harmonics of nth order (n is an odd number not smaller than 3) included in the output signals of the first differential pair and the output signals of the second differential pair cancel each other.

4. An amplifier comprising:
a first differential pair which receives differential input signals; and
a group of second differential pairs, the group containing a plurality of differential pairs which are connected in parallel and each receive the differential input signals, wherein
the first differential pair and the group of second differential pairs are connected such that the group of second differential pairs receive part of a tail current of the first differential pair, and such that output signals of the first differential pair and output signals of the group of second differential pairs cancel each other.

5. The amplifier according to claim 1, further comprising a common-mode feedback circuit which adjusts direct-current components of differential output signals of the amplifier to a predetermined voltage.

6. The amplifier according to claim 2, further comprising a common-mode feedback circuit which adjusts direct-current components of differential output signals of the amplifier to a predetermined voltage.

7. The amplifier according to claim 3, further comprising a common-mode feedback circuit which adjusts direct-current components of differential output signals of the amplifier to a predetermined voltage.

8. The amplifier according to claim 4, further comprising a common-mode feedback circuit which adjusts direct-current components of differential output signals of the amplifier to a predetermined voltage.

9. A communication system comprising:
a local oscillator which oscillates at a predetermined frequency;
a frequency conversion circuit which mixes an oscillation signal from the local oscillator and a signal received by an antenna; and
the amplifier according to claim 1, which amplifies a signal generated by the frequency conversion circuit.
